(19) United States
(12) Patent Application Publication
(10) Pub. No.: US 2015/0369875 A1
(43) Pub. Date: Dec. 24, 2015

(54) BATTERY STATE ESTIMATING DEVICE

(71) Applicant: SANYO ELECTRIC CO., LTD., Daito-shi, Osaka (JP)

(72) Inventor: YOHEI ISHII, Osaka (JP)

(21) Appl. No.: 14/764,153

(22) PCT Filed: Jan. 31, 2014
(86) PCT No.: PCT/JP2014/000511

§ 371 Date: Jul. 28, 2015

(30) Foreign Application Priority Data
Feb. 1, 2013 (JP) 2013-017981

(51) Int. Cl. G01R 31/36; H02J 7/00

(52) U.S. Cl. CPC G01R 31/3651; G01R 31/3606; H02J 7/007

(57) ABSTRACT

Battery state estimating device includes: measured value acquiring unit for acquiring a measured value in a predetermined measurement period of the time-varying battery state of battery after charge or discharge; model function determining unit for determining, based on the measured value, the function forms of a plurality of model functions for modelling the battery state; multiple prediction unit for predicting the variation of the battery state using each of the plurality of model functions whose function forms are determined; and estimating unit for calculating an estimated stable value of the battery state on the basis of the result by multiple prediction unit.

### TECHNICAL FIELD

The present invention relates to a battery state estimating device for estimating the stable value of a time-varying battery state.

### BACKGROUND ART

A battery has a capacity component in an equivalent circuit form, so that much time is taken until the inter-terminal voltage becomes stable after charge or discharge.

Patent Literature 1 discloses that the open circuit voltage of a battery is estimated by linear approximation from data in 20-30 min from the completion of charge or discharge. Patent Literature 2 discloses that, as an approximate equation of the open circuit voltage of a secondary battery, a coefficient of a quaternary or more index attenuation function is determined and used. Patent Literature 3 discloses that a reciprocal function is used for estimating the stable open circuit voltage of a battery.

### CITATION LIST

### Patent Literature

PTL 1: Unexamined Japanese Patent Publication No. 2002-250757
PTL 2: Unexamined Japanese Patent. Publication No. 2005-43339
PTL 3: Unexamined Japanese Patent Publication No. 2008-268161

### SUMMARY OF THE INVENTION

### Technical Problem(s)

In a battery after charge or discharge, accurate prediction of the time-varying battery state is required.

### Solution(s) to Problem(s)

The battery state estimating device of the present invention includes the following components:

a measured value acquiring unit for acquiring a measured value in a predetermined measurement period of the time-varying battery state of a battery after charge or discharge;

a model function determining unit for determining, based on the measured value, the function forms of a plurality of model functions for modelling the battery state;

a multiple prediction unit for predicting the variation of the battery state using each of the plurality of model, functions whose function forms are determined; and

an estimating unit for calculating an estimated stable value of the battery state based on the result by the multiple prediction unit,

### Advantageous Effect(s) of Invention

Thanks to the above-mentioned configuration, the time-varying battery state of the battery after charge or discharge can be accurately predicted,

### BRIEF DESCRIPTION OF DRAWINGS

FIG. 1 is a block diagram of a battery charge/discharge control system including a battery state estimating device in an example in accordance with an exemplary embodiment of the present invention.

FIG. 2 is a diagram showing an example of a plurality of model functions used in the battery state estimating device in the example in accordance with the exemplary embodiment of the present invention.

FIG. 3 is a diagram showing another example of the plurality of model functions used in the battery state estimating device in the example in accordance with the exemplary embodiment of the present invention.

FIG. 4 is a flowchart showing the procedures of battery state estimation executed by the battery state estimating device in the example in accordance with the exemplary embodiment of the present invention.

FIG. 5 is a diagram showing the weighting used in the battery state estimating device in the example in accordance with the exemplary embodiment of the present invention.

### DESCRIPTION OF EMBODIMENT(S)

An exemplary embodiment of the present invention is described hereinafter in detail with reference to the accompanying drawings. The open-circuit voltage characteristic of a battery and the function forms of a plurality of model functions (described later) are examples for description, and can be appropriately modified in accordance with the specification or characteristic of the battery as a target of a battery state estimating device.

Hereinafter, corresponding elements in all drawings are denoted with the same reference marks, and the duplication of the descriptions is omitted.

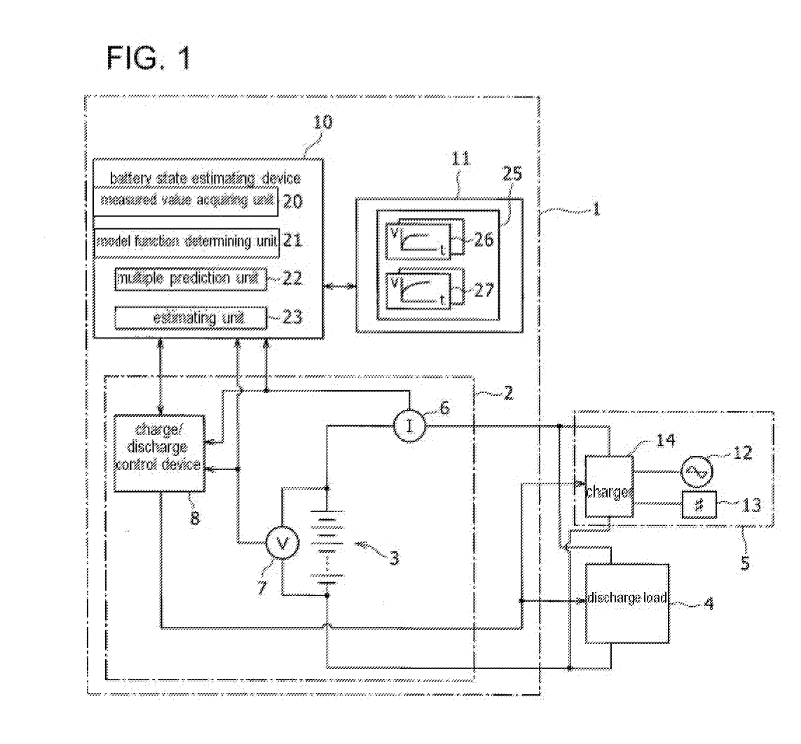

FIG. 1 is a block diagram of battery charge/discharge control system 1. Battery charge/discharge control system 1 includes battery charge/discharge unit 2. Battery charge/discharge unit 2 includes battery 3, current detecting unit 6 for detecting the current input to or output from battery 3 when battery 3 is connected to charge power source 5 or discharge load 4, and voltage detecting unit 7 for detecting the inter-terminal voltage of battery 3. Battery charge/discharge control system 1 further includes charge/discharge control device 8, battery state estimating device 10, and storage unit 11 connected to battery state estimating device 10. FIG. 1 shows discharge load 4 and charge power source 5 connected to battery charge/discharge unit 2, though discharge load 4 and charge power source 5 are not components of battery charge/discharge control system 1.

Battery 3 as a target of the battery state estimation is a battery whose battery state varies with time. In this case, battery 3 is a chargeable/dischargeable secondary battery. As the secondary battery, a lithium-ion battery can be used as a target of the battery state estimation. In addition, a nickel-metal-hydride battery, alkaline battery, or lead acid storage battery may be used as a target of the battery state estimation,

Discharge load 4 is an apparatus utilizing the discharge power supplied from battery 3. In this case, a household lamp, an electric instrument such as a personal computer, or a luminaire or electric instrument in a factory is employed. In addition, a rotary electric machine or electric instrument mounted in a vehicle may be employed.

Charge power source 5 is a power generating device such as commercial power source 12 or solar battery 13, and is connected to battery 3 via charger 14.

Current detecting unit 6 is a current detecting means for distinctly detecting the charge current input from charge power source 5 to battery 3 and the discharge current output from battery 3 to discharge load 4. As current detecting unit 6, an appropriate ammeter can be employed.

The current value detected by current detecting unit 6 is transmitted to charge/discharge control device 8 through an appropriate signal line, and is used for control of battery charge/discharge unit 2, such as recognition of the difference between a charge/discharge command value and a measured value. Here, a current value having a plus sign is a charge current value, and a current value having a minus sign is a discharge current value. Furthermore, the current value detected by current detecting unit 6 is a current characteristic value as one of the battery states. Therefore, when battery state estimating device 10 performs estimation related, to the current characteristic value, the current value detected by current detecting unit 6 serves as a measured current value used as a basis of estimation. At this time, the current value is transmitted to battery state estimating device 10 through an appropriate signal line, and is used for estimation processing such as calculation of the state of charge (SOC) showing the charge state of the battery.

Voltage detecting unit 7 is a voltage detecting means for detecting the inter-terminal voltage of battery 3. As voltage detecting unit 7, an appropriate voltmeter can be employed. The voltage value detected by voltage detecting unit 7 is transmitted to charge/discharge control device 8 through an appropriate signal line, and is used for monitoring or the like of the voltage state of the battery. The voltage value detected by voltage detecting unit 7 is a voltage characteristic value as one of the battery states. Therefore, when battery state estimating device 10 performs estimation related to the voltage characteristic value, the voltage value detected by voltage detecting unit 7 is transmitted to battery state estimating device 10 through an appropriate signal line, and serves as a measured voltage value used as a basis of estimation.

Charge/discharge control device 8 outputs a charge/discharge command in accordance with a request from discharge load 4 or charge power source 5, and controls the charge/discharge of battery 3. Charge/discharge control device 8 can be formed of an appropriate computer.

Battery state estimating device 10 is a device for estimating the stable value of a time-varying battery state using the detected value of current detecting unit 6 or detected value of voltage detecting unit 7. Battery state estimating device 10 can be formed of an appropriate computer.

In this case, the time-varying battery state means the state of battery 3 when battery 3 is charged or discharged. In this battery state, the input or output current value and the inter-terminal voltage vary with time depending on the capacity component, inductance component, and resistance component of battery 3. Therefore, the time-varying battery state includes the SOC (State Of Charge) that shows the charge state of the battery in addition to the current state and voltage state of battery 3.

For example, when a charge command is output from charge/discharge control device 8 to battery 3, a predetermined charge is applied to battery 3 from the charge power source. After the charge is completed, battery 3 comes into an open circuit state where battery 3 is separated from charge power source 5. According to the observation of the open circuit voltage, the inter-terminal voltage decreases with time. Conversely, when a discharge command is output from charge/discharge control device 8 to battery 3, a predetermined discharge is applied, to discharge load 4 from battery 3. After the discharge is completed, battery 3 comes into an open circuit state where battery 3 is separated from discharge load 4. The inter-terminal voltage of battery 3 in the open circuit state is open circuit voltage (OCV). According to the observation of the open circuit voltage, the open circuit voltage gradually decreases with time after the completion of the charge, and the open circuit voltage gradually increases with time after the completion of the discharge. Thus, the open circuit voltage is one of the time-varying battery states.

In order to obtain a stable value of the time-varying open circuit voltage after the completion of the charge/discharge, a time period is taken until the open circuit voltage becomes stable. The time period taken until the open circuit voltage becomes stable is several minutes in some cases, but is several hours in quite a lot of cases. Hereinafter, the open circuit voltage is described as a time-varying battery state. In that case, battery state estimating device 10 estimates the stable value of the open circuit voltage in a short time by calculation.

Battery state estimating device 10 includes the following components:

measured value acquiring unit 20 for acquiring a measured value of the time-varying battery state in a predetermined measurement period;

model function determining unit 21 for determining, based on the measured value, the function forms of a plurality of model functions for modelling the battery state;

multiple prediction unit 22 for predicting the variation of the battery state using each of the plurality of model functions whose function forms are determined; and

estimating unit 23 for calculating an estimated stable value of the battery state on the basis of the result by the multiple prediction unit.

Such functions can be achieved when battery state estimating device 10 executes software. Specifically, these functions can be achieved when battery state estimating device 10 executes a battery state estimation program. A part of the functions may be achieved by hardware.

Storage unit 11 connected to battery state estimating device 10 is a memory for storing a program or the like used by battery state estimating device 10. Specifically, storage unit 11 stores, as model function file 25, the plurality of model functions for modelling the battery state. Estimating unit 23 of battery state estimating device 10 selects two or more appropriate model functions from the plurality of model functions stored in model function file 25 of storage unit 11, and estimates the stable value of the battery state on the basis of a plurality of predicted values predicted using the two or more model functions.

The reason why the plurality of model functions are used is that the voltage behavior after the charge or discharge of battery 3 is complicatedly affected by the type of battery 3, the environmental temperature, the current amount during charge/discharge, or the value of the SOC. Therefore, the same model function, is not necessarily appropriate for the complicated cases. The reason is that there are many cases where the battery state of battery 3 cannot be modelled with one model function in the whole charge/discharge region. Even when one model function can be used, the same value is not always appropriate for the parameter for determining the function form of the model function.

A plurality of model functions are stored in model function file 25. One of them is first model function 26 showing that the battery state varies exponentially with time. Second model function 27 showing that the battery state varies logarithmically with time is also stored. The other model function includes a linear model, function showing that the battery state linearly varies with time, an inversely proportional model function showing that the battery state varies inversely proportionally to time, a function, using a linear sum of exponentiation of elapsed time t, or a sigmoid function showing that the battery state asymptotically approaches a convergence value with time. Hereinafter, the case is described where first model function 26 and second model function 27 are used as the plurality of model functions in battery state estimating device 10.

In the above description, storage unit 11 is independent of battery state estimating device 10. However, storage unit 11 may be included in battery state estimating device 10. In the above description, battery state estimating device 10 is an independent device separate from charge/discharge control device 8. However, battery state estimating device 10 may be formed as a part of charge/discharge control device 8.

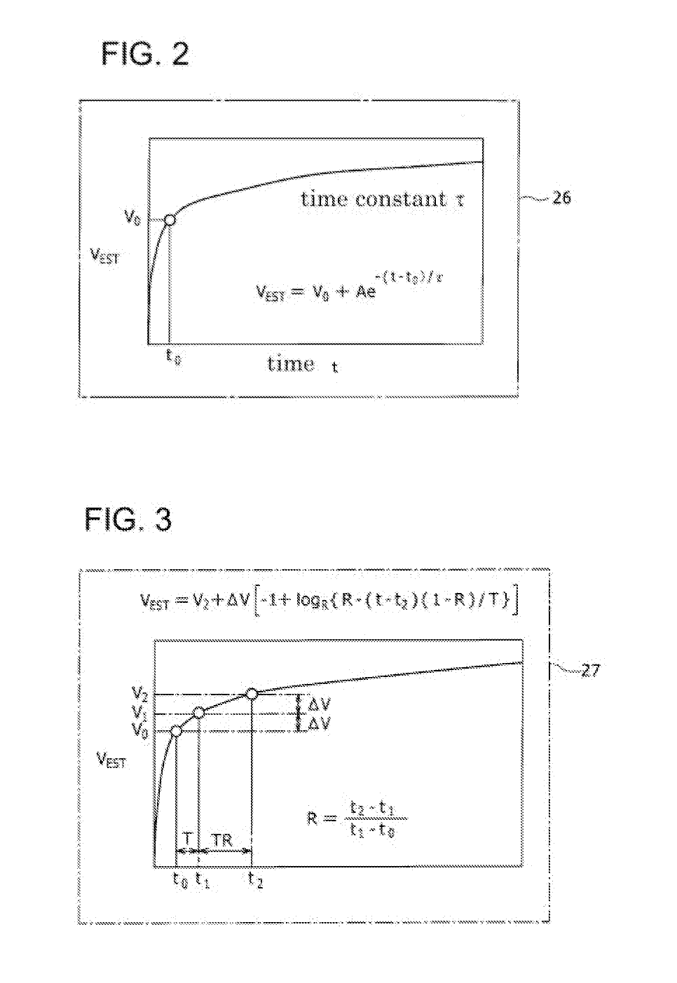

Next, first model function 26 and second model function 27 stored in model function file 25 are described with reference to FIG. 2 and FIG. 3. First model function 26 and second model function 27 are functions showing the relationship between predicted value V_{EST} of the open circuit voltage of battery 3 and elapsed time t from the completion of discharge.

FIG. 2 is a diagram showing first model function 26. First model function 26 has a function form shown in equation (1) when the open circuit voltage at time t₀ is denoted with V₀ as the initial value. A and time constant τ are parameters for determining a specific function form. Thus, first model function 26 has a function form in which the open circuit voltage as a battery state varies exponentially with time.

[Equation 1]

V_{EST}=V₀+Ae^{-(t-t}^{₀}^{)/τ} (1)

FIG. 3 is a diagram showing second model function 27. Second model function 27 has a function form shown in equation (2). Here, the open circuit voltage at time t₀ is denoted with V₀ as the initial value, the open circuit voltage at time t₁ is denoted with V₁, and the open circuit voltage at time t₂ is denoted with V₂. R, T, and ΔV are parameters for determining a specific function form. R is expressed by equation (3).

$$\begin{matrix}[ Equation 2 ] & \\ {V}_{EST} = {V}_{2} + Δ V [ - 1 + {log}_{R} \{ R - ( t - {t}_{2} ) ( 1 - R ) \text{/} T \} ] & ( 2 ) \\ [ Equation 3 ] & \\ R = \frac{{t}_{2} - {t}_{1}}{{t}_{1} - {t}_{0}} & ( 3 )\end{matrix}$$

Second model function 27 has a function form in which the open circuit voltage as a battery state varies logarithmically with time as shown in equation (2). In this case, when the unit increase of the open circuit voltage increasing with time is set at ΔV, the elapsed time for first increase by ΔV is set at T=t₁−t₀, the elapsed time for second increase by ΔV is set at TR=t₂−t₁, and R shown in equation (3) is determined. Then, in this function form, the elapsed time for third increase by ΔV is set at TR²=t₃−t₂, the elapsed time for fourth increase by ΔV is set at TR³=t₄−t₃, and the elapsed time for n-th increase by ΔV is set at TR⁽ⁿ⁻¹⁾. Thus, second model function 27 has a function form determined by R, T, and ΔV as parameters.

First model function 26 is compared with second model function 27. When time constant τ during the decrease of the open circuit voltage with time is large, the error is small even when first model function 26 is used for estimating the stable value of the open circuit voltage. When time constant τ during the decrease of the open circuit voltage with time is small, the error of the measured initial value or τ greatly affects the estimation when first model function 26 is used for estimating the stable value of the open circuit voltage. In that case, the error is smaller when second model function 27 having a moderate function form is used for estimating the stable value of the open circuit voltage.

First model function 26 of FIG. 2 and second model function 27 of FIG. 3 are stored in model function file 25 of storage unit 11. FIG. 2 and FIG. 3 show the case of discharge. Even in the case of charge, however, first model function 26 and second model function 27 have the same function forms as those in the case of discharge, and only the parameters and signs are changed.

In FIG. 2 and FIG. 3, the pattern of each of first model function 26 and second model function 27 stored in model function file 25 is described as a map. The pattern of model function file 25 may be a pattern other than a map as long as the value showing the battery state is associated with time. For example, a pattern such as a look-up table, an equation, or a read only memory (ROM) that, upon receiving time t, outputs a value showing the battery state may be employed.

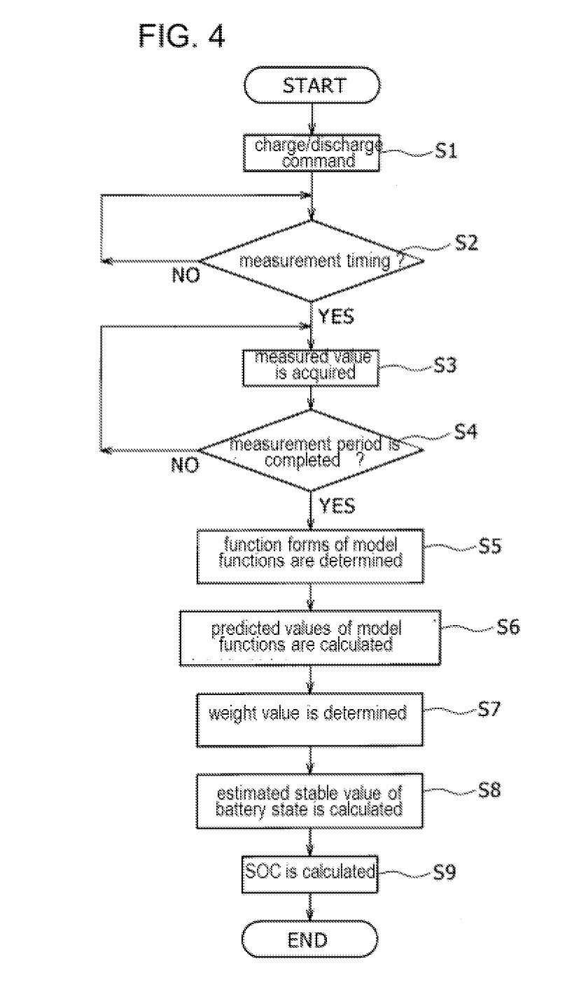

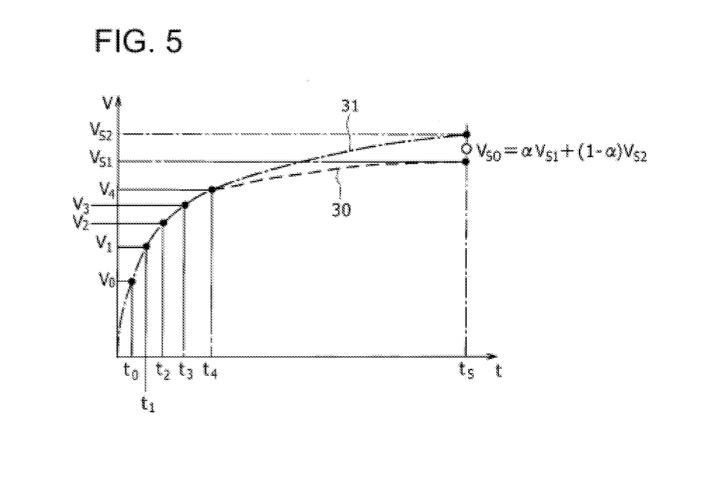

The operation of the above-mentioned configuration, especially each function of battery state estimating device 10, is described in more detail using FIG. 4 and FIG. 5. FIG. 4 is a flowchart showing the procedures of battery state estimation. The procedures of FIG. 4 correspond to processing procedures of the battery state estimation program, respectively. FIG. 4 illustrates, as one example, procedures of estimating the stable value of the open circuit voltage when battery 3 is discharged. FIG. 5 is a diagram showing the process of the calculation of the estimated stable value of FIG. 4.

In FIG. 4, the battery state is estimated when a charge/discharge command is output from charge/discharge control device 8 (S1). In this case, a discharge command is output from charge/discharge control device 8. When the discharge command is output, discharge from battery 3 to discharge load 4 is performed in accordance with the contents of the discharge command. In this stage, battery state estimating device 10 does not do anything. After S1, battery state estimating device 10 determines whether it is a measurement timing (S2). The measurement timing means the timing when a measured value of the inter-terminal voltage of battery 3 can be acquired as a premise in order to estimate the stable value of the open circuit voltage after the completion of the discharge of battery 3. In this case, when battery 3 comes into the open circuit state, the determination result in S2 becomes YES. For example, it is determined whether the discharge of battery 3 is completed, and, when the completion of the discharge is determined, the determination result in S2 is YES. Specifically, when the discharge command output from charge/discharge control device 8 includes a discharge completion time, the determination result in S2 becomes YES after the discharge completion time elapses.

When the determination result in S2 becomes YES, a measured value of the open circuit voltage of battery 3 is acquired (S3). This processing procedure is executed by the function of measured value acquiring unit 20 of battery state estimating device 10. In this procedure, a detected value transmitted from voltage detecting unit 7 is acquired. A plurality of measured values are sampled at different times.

Next, it is determined whether the measurement period is completed (S4). The measurement period is set so that the data of the measured values acquired in S3 is sufficient for determining the parameters of the function form of first model function 26 and the parameters of the function form of second model function 27. The measurement period is set in consideration of not only the number of data but also the fact that the acquired measured values are disposed at an appropriate voltage interval. When the measurement period is excessively long, the measured values become closer to the stable value of the open circuit voltage and the importance of the estimation is low. Preferably, the measurement period is minimized in consideration of the required accuracy of the estimation of the stable value of the open circuit voltage.

When sufficient measured values are acquired in S4, the parameters of the function form of first model function 26 and the parameters of the function form of second model function 27 are determined (S5). This processing procedure is executed by the function of model function determining unit 21 of battery state estimating device 10. In this procedure, calculation for determining parameters A and τ for first model function 26 and parameters R, T, and ΔV for second model function 27 is performed. In order to determine a plurality of parameters of each function using the plurality of measured values, a publicly known technology such as the method of least squares can be used.

When the parameters of each of first model function 26 and second model function 27 are determined, and each function form is determined in S5, the value of the open circuit voltage at predetermined prediction time t_{S} is calculated as a predicted value using each of first model function 26 and second model function 27 (S6). This processing procedure is executed by the function of multiple prediction unit 22 of battery state estimating device 10. Prediction time t_{S} is set at the time at which the open circuit voltage of battery 3 is considered to become a sufficiently stable value. Prediction time t_{S} of battery 3 can be previously determined by an experiment. As one example, the measurement period is set at 10 min., and prediction time t_{S} can be set at a time after 1 h.

FIG. 5 shows the calculation of predicted value V_{S1} by first model function 26 and predicted value V_{S2} by second model function 27 at time t₀. In FIG. 5, the horizontal axis shows time, and vertical axis shows open circuit voltage V. The measurement period is from time t₀ to time t₄, and five measured values V₀ to V₄ are acquired in this case. FIG. 5 shows function form 30 of first model function 26 and function form 31 of second model function 27 that are determined on the basis of five measured values V₀ to V₄. On function form 30, the value at time t_{S} is predicted value V_{S1} by first model function 26. Similarly, on function form 31, the value at time t_{S} is predicted value V_{S2} by second model function 27.

The description returns to FIG. 4, and a weight value is determined in S7. The weight value is used for calculating the most likely estimated stable value of the open circuit voltage using predicted value V_{S1} by first model function 26 and predicted value V_{S2} by second model function 27, and determines which of the two predicted values is enhanced. In other words, using weight value α, the estimated stable value is calculated by the expression of estimated stable value=αV_{S1}+(1−α)V_{S2}.

Weight value α can be determined on the basis of the parameter values of the function form of first model function 26 and the parameter values as the coefficients of the function form of second model function 27. As one example of determining weight value α, weight value α can be determined on the basis of time constant τ when the open circuit voltage increases with time. As discussed above, when time constant τ is large, it is preferable to apply first model function. 26 to estimation of the stable value of the open circuit voltage. When time constant τ is small, it is preferable to apply second model function 27. Therefore, weight value α can be determined in accordance with equation (4).

$$\begin{matrix}[ Equation ( 4 ) ] & \\ \begin{matrix}τ < 100 s \text{:} & α = 0.5 \\ 100 S ≦ τ < 600 s \text{:} & α = 0.7 \\ 600 S ≦ τ \text{:} & α = 0.9\end{matrix} \} & ( 4 )\end{matrix}$$

In equation (4), weight value α is set constant, and can be determined in consideration of the type of battery 3, the environmental temperature, the current amount during charge/discharge, the value of the SOC, or prediction time t_{S}. Weight value α may be determined by learning. For example, a model is learned using the data previously collected by a machine learning technique such as neural network, and weight value α is calculated using the learned model.

When weight value α is determined in S7, the most likely estimated stable value of the open circuit voltage is calculated using predicted value V_{S1} by first model function 26 and predicted value V_{S2} by second model function 27 that are calculated in S6 (S8). This processing procedure is executed by the function of estimating unit 23 of battery state estimating device 10. In other words, using weight value α, the estimated stable value is calculated by the expression of estimated stable value=αV_{S1}+(1−α)V_{S2}. FIG. 5 shows estimated stable value V_{S0} using weight value α.

When the estimated stable value of the open circuit voltage of battery 3 is acquired in S8, the SOC of battery 3 after the completion of the discharge can be calculated using the previously determined relationship between the Open circuit voltage and the SOC (S9).

Thus, the open circuit voltage is estimated by sampling the inter-terminal voltage of battery 3 after charge or discharge, so that the SOC based on the voltage can be calculated in a shorter time than ever. Furthermore, the open circuit voltage is estimated by using and weighting a plurality of model functions for prediction, so that the behavior of the open circuit voltage complicatedly varying in various conditions can be flexibly handled and the estimation accuracy can be improved.

In the above description, the weighting is performed using two predicted values by two model functions. When N (3 or more) predicted values V_{S1} to V_{SN} are used, however, the weighting in accordance with equation (5) can be performed using N weight values α₁ to α_{N}. Here, the sum total of N weight values is 1.

[Equation (5)]

V_{S0}=α₁V_{S1}+α₂V_{S2}+ . . . α_{N}V_{SN} (5)

In the above description, after the completion of charge or discharge, the open circuit voltage is estimated on the basis of the measured values acquired in one measurement period. When the estimation is performed in several measurement periods and the result is sequentially updated, however, the estimation accuracy can be improved.

### REFERENCE MARKS IN THE DRAWINGS

1 battery charge/discharge control system
2 battery charge/discharge unit
3 battery
4 discharge load
5 charge power source
6 current detecting unit
7 voltage detecting unit
8 charge/discharge control device
10 battery state estimating device
11 storage unit
12 commercial power source
13 solar battery
14 charger
20 measured value acquiring unit
21 model function determining unit.
22 multiple prediction unit
23 estimating unit
25 model function file
26 first model function
27 second model function
30 function form (of first model function)
31 function form (of second model function)

1. A battery state estimating device comprising:
a measured value acquiring unit for acquiring a measured value in a predetermined measurement period of a time-varying battery state of a battery after charge or discharge;
a model function determining unit for determining, based on the measured value, function forms of a plurality of model functions for modelling the battery state;
a multiple prediction unit for predicting variation of the battery state using each of the plurality of model functions whose function forms are determined; and
an estimating unit for calculating an estimated stable value of the battery state based on prediction results by the multiple prediction unit.

2. The battery state estimating device according to claim 1, wherein
the plurality of model functions at least include:
a first model function showing that the battery state varies exponentially with time; and
a second model function showing that the battery state varies logarithmically with time.

3. The battery state estimating device according to claim 1, wherein
the estimating unit weights the prediction results based on coefficients of the determined model functions, and calculates the estimated stable value of the battery state by adding the weighted prediction results.

4. The battery state estimating device according to claim 1, wherein the battery state includes an open circuit voltage of the battery.

5. The battery state estimating device according to claim 4, wherein the battery state includes a charge state of the battery calculated based on the open circuit voltage of the battery.

6. The battery state estimating device according to claim 2, wherein the estimating unit weights the prediction results based on coefficients of the determined model functions, and calculates the estimated stable value of the battery state by adding the weighted prediction results.
